(19) United States
(12) Patent Application Publication
(10) Pub. No.: US 2008/0166854 A1
(43) Pub. Date: Jul. 10, 2008

(54) SEMICONDUCTOR DEVICES INCLUDING TRENCH ISOLATION STRUCTURES AND METHODS OF FORMING THE SAME

(76) Inventors: Dong-Suk Shin, Gyeonggi-do (KR); Tae-Gyun Kim, Seoul (KR)

Correspondence Address: MYERS BIGEL SIBLEY & SAJOVEC, PO BOX 37428, RALEIGH, NC, 27627, US

(21) Appl. No.: 12/052,257

(22) Filed: Mar. 20, 2008

Related U.S. Application Data
(63) Continuation-in-part of application No. 11/393,546, filed on Mar. 30, 2006.

(30) Foreign Application Priority Data
Sep. 9, 2005 (KR) 2005-84254

(51) Int. Cl. H01L 21/76

(52) U.S. Cl. 438/427; 257/E21.546

(57) ABSTRACT

Trench isolation methods include forming a first trench and a second trench in a semiconductor substrate. The second trench has a larger width than the first trench. A tower isolation layer is formed on the semiconductor substrate using a first high density plasma deposition process. The lower isolation layer has a first thickness on an upper sidewall of the first trench and a second thickness on an upper sidewall of the second trench. The second thickness is greater than the first thickness. An upper isolation layer is formed on the semiconductor substrate including the lower isolation layer using a second high density plasma deposition process, different from the first high density plasma deposition process. The second high density plasma deposition process includes an H₂ treatment process.

### CROSS-REFERENCE TO RELATED APPLICATIONS

This application is a continuation-in-part of U.S. patent application Ser. No. 11/393,546 filed Mar. 30, 2006, which claims priority from Patent Application No. 2005-0084254 filed Sep. 9, 2005, in the Korean Intellectual Property Office, the disclosures of which are hereby incorporated herein by reference as if set forth in their entireties.

### BACKGROUND OF THE INVENTION

The present invention relates to semiconductor devices and methods of fabricating the same, and more particularly, to semiconductor devices having a trench isolation structure and methods of fabricating the same.

As semiconductor devices become more highly integrated, an increase in aspect ratio of an isolation trench of the devices is generally required. The increase in aspect ratio typically makes it more difficult to fill the trench with an insulating layer without voids. A high-density plasma chemical vapor deposition (HDPCVD) technique having an excellent gap filling property is known for use in forming trench isolation layers in highly integrated semiconductor devices.

FIGS. 1 and 2 are cross-sectional views illustrating a conventional trench isolation method. Referring to FIG. 1, a pad oxide layer and a pad nitride layer are sequentially formed on a semiconductor substrate 11. The pad oxide layer and the pad nitride layer are continuously patterned to form a pad oxide pattern 14 and a pad nitride pattern 15, which expose predetermined regions of the semiconductor substrate 11. The exposed semiconductor substrate 11 is etched using the pad nitride pattern 15 as an etch mask to form trenches 16 and 18. As a result, first trenches 16 are formed in a cell region C of the semiconductor substrate 11 to define a cell active region 12. In addition, second trenches 18 are formed in a peripheral circuit region P of the semiconductor substrate 11 to define a peripheral active region 13. The cell active region 12 and the peripheral active region 3 are illustrated formed in the shape of a trapezoid having a top width smaller than the bottom width.

The second trenches 18 generally have larger widths than those of the first trenches 16. That is, the second trenches 18 having larger widths than those of the first trenches 16 are formed in the peripheral circuit region P. The process of etching the exposed semiconductor substrate 11 to form trenches may be, for example, an anisotropic etching process, such as dry etching. In addition, simultaneously forming the first and second trenches 16 and 18 may provide a reduction of process time. The sidewalls of the cell active region 12 are illustrated as having different slopes from sidewalls of the peripheral active region 13. Specifically, a first crossing angle θ1 is formed between a top surface and the sidewall of the cell active region 12, and a second crossing angle θ2 is formed between a top surface and the sidewall of the peripheral active region 13. In general, the second crossing angle θ2 is larger than the first crossing angle θ1. That is, the sidewalls of the cell active region 12 may be close to 90°, whereas the sidewalls of the peripheral active region 13 may have gentler slopes than the sidewalls of the cell active region 12.

The semiconductor substrate 11 having the first and second trenches 16 and 18 is thermally oxidized to form a sidewall oxide layer 19 on inner walls of the first and second trenches 16 and 18. A conformal silicon nitride layer 20 is formed on the entire surface of the semiconductor substrate 11 having the sidewall oxide layer 19.

Subsequently, a process for forming an isolation layer is performed to fill the first and second trenches 16 and 18. The isolation layer forming process employs a HDPCVD technique. The isolation layer forming process employing the HDPCVD technique includes a deposition process and a sputter etching process, which are alternately and repeatedly performed. A preliminary oxide layer 22 is formed on the entire surface of the semiconductor substrate 11 having the silicon nitride layer 20 during the deposition process, and the preliminary oxide layer 22 is etched by the sputter etching process. In addition, while the sputter etching process is performed, the preliminary oxide layer 22 sputtered from sidewalls of the first and second trenches 16 and 18 may be redeposited on opposite sidewalls. As a result, an isolation layer 22′ is formed within the first and second trenches 16 and 18.

The isolation layer 22′ having a first thickness 31 is formed on an upper sidewall of the first trench 16, and the isolation layer 22′ having a second thickness 32 is formed on an upper sidewall of the second trench 18. The redeposition generally more readily occurs when the distance between the sidewalls is close to each other. The distance between the sidewalls facing each other in the cell active region 12 is smaller than the distance between the sidewalls facing each other in the peripheral active region 13. Accordingly, the first thickness 31 is larger than the second thickness 32. When the deposition process and the sputter etching process are repeatedly performed, overhangs typically occur on the upper sidewalls of the first trenches 16. The overhang generally causes voids within the first trenches 16.

Referring now to FIG. 2, methods of applying high bias power to a HDPCVD apparatus has been proposed in order to minimize the overhang and to enhance the burial properties of the trenches 16 and 18. However, the high bias power may cause plasma damage to occur on the sidewalls of the peripheral active region 13 and the sidewalls of the cell active region 12. As described with reference to FIG. 1, the isolation layer 22′ having the relatively small thickness 32 is formed on the tipper sidewall of the second trench 18. Accordingly, the upper sidewall of the peripheral active region 13 is relatively more likely to be damaged by the plasma. When the plasma damage is repeatedly applied to the upper sidewall of the peripheral active region 13, the pad nitride pattern 15 may be detached from the semi conductor substrate 11.

Further methods for trench isolation are described in U.S. Pat. No. 6,806,165 B1 entitled “Isolation Trench Fill Process” to Hopper et al. As described in Hopper et al, a conformal HDP liner is formed on a semiconductor substrate having trenches. A HDP oxide layer is formed on the semiconductor substrate having the HDP liner to fill the trench. The process of forming the HDP liner and the process of forming the HDP oxide layer are continuously performed within the same apparatus.

Accordingly, improved trench isolation methods for simultaneously burying a trench having a narrow width and a trench having a large width are desirable.

As semiconductor (integrated circuit) devices become more highly integrated, trenches in cell regions are being formed to have a smaller width as discussed above. More particularly, an individual semiconductor substrate may have formed thereon both a first trench having a small width and a second trench having a larger width than the first trench, which respective trenches may need to be formed simultaneously. As described above, the first trench may define a cell active region in the cell region and the second trench may define a peripheral active region in a peripheral circuit region.

A high density plasma chemical vapor deposition process used to fill the first and second trenches with an insulating layer may include a deposition process and a sputter etching process, which are alternately and repeatedly performed as discussed above. The repetition of the deposition and sputter etching processes may result in a defect, such as sidewall oxide lifting. Such a defect may be commonly found, for example, at an upper part of the cell active region.

### SUMMARY OF THE INVENTION

Some embodiments of the present invention provide trench isolation methods including forming a first trench and a second trench in a semiconductor substrate. The second trench has a larger width than the first trench. A lower isolation layer is formed on the semiconductor substrate using a first high density plasma deposition process. The lower isolation layer has a first thickness on an upper sidewall of the first trench and a second thickness on an upper sidewall of the second trench. The second thickness is greater than the first thickness. The second thickness may be at least about one and a half times as large as the first thickness. An upper isolation layer is formed on the semiconductor substrate including the lower isolation layer using a second high density plasma deposition process, different from the first high density plasma deposition process. The second high density plasma deposition process includes an H, treatment process.

In other embodiments, the first high density plasma deposition process includes positioning the semiconductor substrate including the first and second trenches on a substrate support within a high density plasma chemical vapor deposition (HDPCVD) reactor. With the substrate in the reactor, a first low temperature HDP deposition process is performed on the semiconductor substrate, including injecting a silicon source gas into the HDPCVD reactor. A first etch is also performed on the semiconductor substrate, including injecting an etch gas into the high density plasma chemical vapor deposition reactor. In addition, a first O₂ treatment is performed on the semiconductor substrate, including injecting O₂ into the HDPCVD reactor.

In further embodiments, the first etch and the O₂ treatment are both performed without removing the semiconductor substrate from the HDPCVD reactor therebetween. Forming the lower isolation layer may include repeatedly performing the first low temperature HDP deposition process, the first etch and the first O₂ treatment before forming the upper isolation layer. The silicon source gas may be SiH₄, and the etch gas may be NF₃.

In other embodiments, the second high density plasma deposition process includes the following carried out after forming the lower isolation layer. A second low temperature HDP deposition process is performed on the semiconductor substrate, including injecting a silicon source gas into the HDPCVD reactor. A second etch is performed on the semiconductor substrate, including injecting an etch gas into the HDPCVD reactor. The H₂ treatment is performed on the semiconductor substrate, including injecting H₂ into the HDPCVD reactor and a second O₂ treatment is performed on the semiconductor substrate, including injecting O₂ into the HDPCVD reactor. The second etch and the H₂ treatment may be performed without removing the semiconductor substrate from the HDPCVD reactor therebetween. The silicon source gas for the second low temperature HDP deposition process may be SiH₄, and the etch gas for the second etch may be NF₃.

In further embodiments, the first and second high density plasma deposition processes include maintaining a temperature of the semiconductor substrate at about 200° C. to 500° C. Maintaining the temperature of the semiconductor substrate at about 200° C. to 500° C. may include supplying helium (He) gas to a cooling pipe coupled to a substrate support on which the semiconductor substrate is mounted to maintain the temperature of the semiconductor substrate.

In yet other embodiments, forming the first trench and the second trench includes forming a pad oxide pattern on the semiconductor substrate, forming a pad nitride pattern on the pad oxide pattern and selectively etching the semiconductor substrate using the pad nitride pattern as an etch mask. Forming the first trench and the second trench may be followed by forming a silicon oxide sidewall layer on inner walls of the first and second trenches by thermal oxidation. Forming the first trench and the second trench may be followed by forming a liner conformally covering the semiconductor substrate including the first and second trenches, wherein the liner is a silicon nitride layer, a silicon oxynitride layer and/or a silicon oxide layer.

In further embodiments, trench isolation methods include forming a first trench and a second trench in a semiconductor substrate, the second trench having a larger width than the first trench. An isolation layer is formed on the semiconductor substrate using a high density plasma deposition process. The high density plasma deposition process includes positioning the semiconductor substrate including the first and second trenches on a substrate support within a high density plasma chemical vapor deposition (HDPCVD) reactor. A low temperature HDP deposition process is performed on the semiconductor substrate, including injecting a silicon source gas into the HDPCVD reactor. An etch is performed on the semiconductor substrate, including injecting an etch gas into the HDPCVD reactor. An H₂ treatment process is performed on the semiconductor substrate, including injecting H₂ into the HDPCVD reactor and an O₂ treatment is performed on the semiconductor substrate, including injecting O₂ into the HDPCVD reactor.

In other embodiments, the etch and the H₂ treatment process are performed without removing the semiconductor substrate from the HDPCVD reactor therebetween. The silicon source gas may be SiH₄, and the etch gas may be NF₃. Forming the isolation layer may include maintaining a temperature of the semiconductor substrate at about 200° C. to 500° C. while the high density plasma deposition process is performed. Maintaining the temperature of the semiconductor substrate may include supplying helium (He) gas to a cooling pipe coupled to the substrate support.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are cross-sectional views illustrating a conventional trench isolation method.

FIGS. 3 to 8 are cross-sectional views illustrating a trench isolation method in accordance with some embodiments of the present invention.

FIGS. 9 to 12 are cross-sectional views illustrating a trench isolation method in accordance with further embodiments of the present invention.

FIG. 13 is a schematic view of a high-density plasma chemical vapor deposition apparatus suitable for use in some embodiments of the present invention.

FIG. 14 is a flowchart illustrating a trench isolation method according to further embodiments of the present invention.

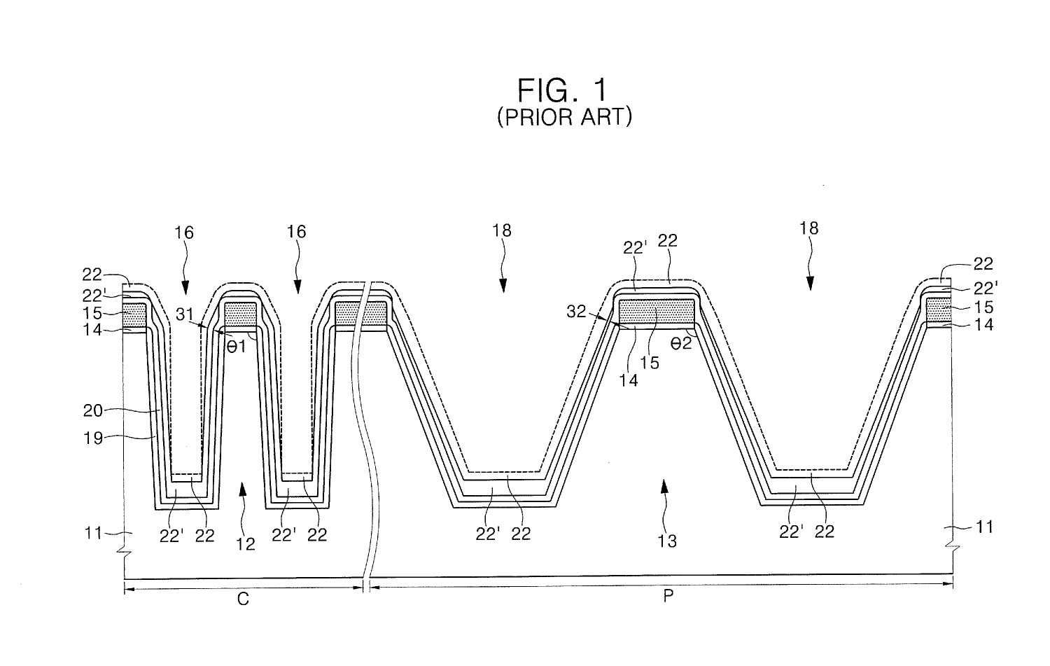

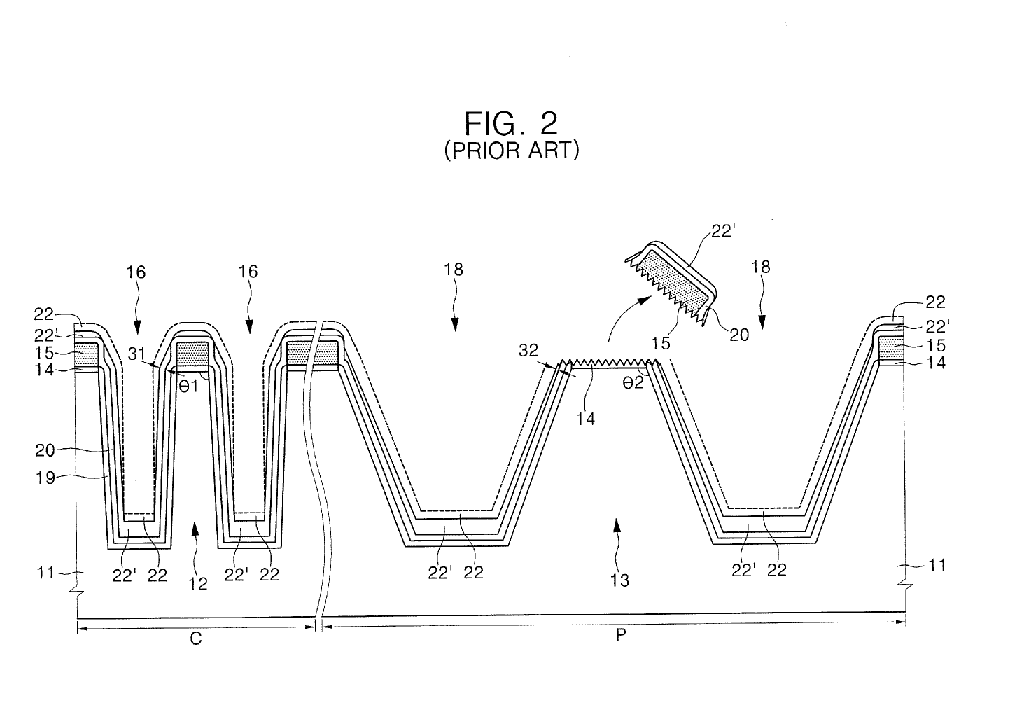

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions Illustrated herein but ire to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terns, such as those defined in commonly used dictionaries, should be interpreted as having a meaning that is consistent with their meaning in the context of the relevant art and will not be interpreted in an idealized or overly formal sense unless expressly so defined herein.

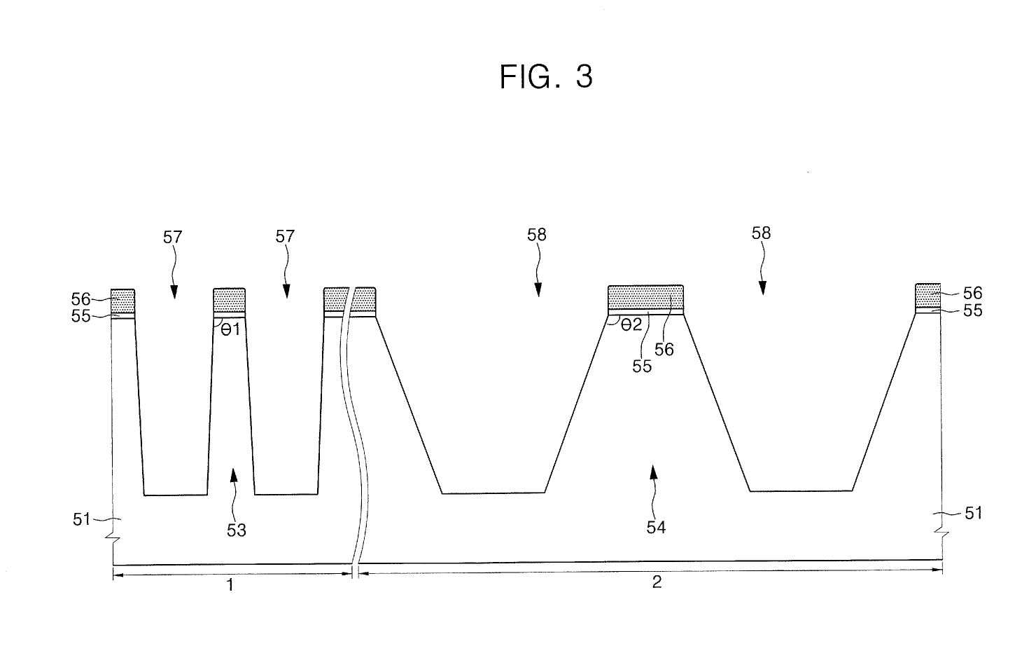

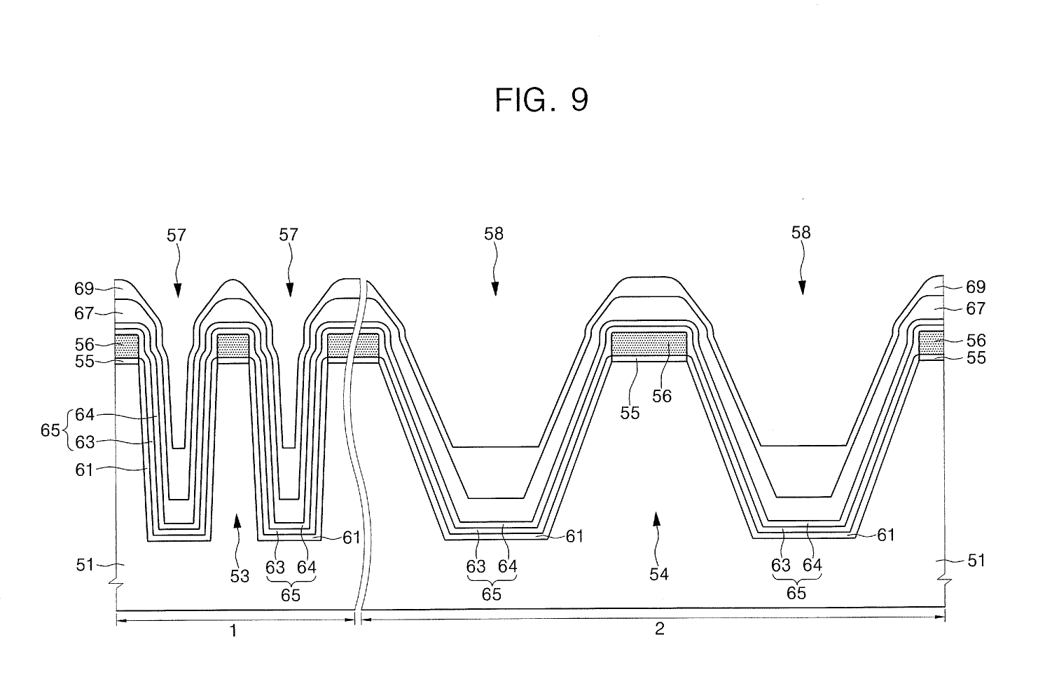

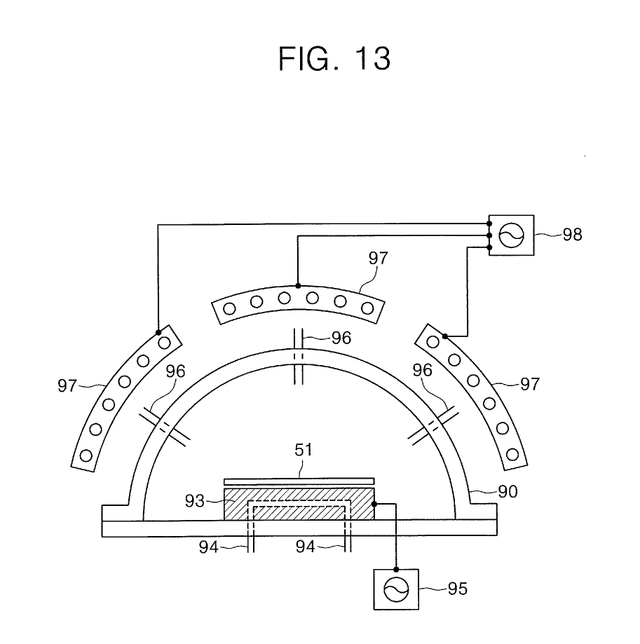

Embodiments of the present invention will now be described with reference to FIGS. 3-13. FIGS. 3 to 8 are cross-sectional views illustrating a trench isolation method in accordance with some embodiments of the present invention, FIGS. 9 to 12 are cross-sectional views illustrating a trench isolation method in accordance with other embodiments of the present invention, and FIG. 13 is a schematic view of a high-density plasma chemical vapor deposition apparatus suitable for use in some embodiments of the present invention, which may be referred to in describing the embodiments of FIGS. 3 to 8 and of FIGS. 9 to 12.

Referring first to FIG. 3, a pad oxide layer and a pad nitride layer are sequentially formed on a semiconductor substrate 51. The pad oxide layer may be formed of a thermal oxide layer. The pad nitride layer may be formed of a silicon nitride layer and/or a silicon oxynitride layer. The pad oxide layer may serve to relieve stress caused by a difference in thermal expansion coefficient between the semiconductor substrate 51 and the pad nitride layer. The pad nitride layer and the pad oxide layer may be continuously patterned to expose a predetermined region of the semiconductor substrate 51 and to form a stacked pad oxide pattern 55 and pad nitride pattern 56. Subsequently, the exposed semiconductor substrate 51 may be, for example, anisotropically etched using the pad nitride pattern 56 as an etch mask to form trenches 57 and 58.

The first trenches 57 are formed in a first region 1 of the semiconductor substrate 51 to define a first active region 53. The second trenches 58 are formed in a second region 2 of the semiconductor substrate 51 to define a second active region 54. The first active region 53 and the second active region 54 may be formed in the shape of a trapezoid having a top width smaller than their bottom width. The first region 1 may be a cell region, and the second region 2 may be a peripheral circuit region.

The second trenches 58 formed in the second region 2 may have larger widths than the first trenches 57. The semiconductor substrate 51 may be etched, for example, by an anisotropic etching process, such as dry etching. In addition, the first and second trenches 57 and 58 may be concurrently formed. The sidewalls of the first active region 53 may be formed to have different slopes from sidewalls of the second active region 54. As shown in FIG. 3, a first crossing angle θ1 is formed between a top surface and the sidewall of the first active region 53 and a second crossing angle θ2 is formed between a top surface and the sidewall of the second active region 54. The second crossing angle θ2 may be larger than the first crossing angle θ1. That is, the sidewalls of the illustrated first active region 53 are close to 90°, whereas the sidewalls of the second active region 54 have gentler slopes than the sidewalls of the first active region 53.

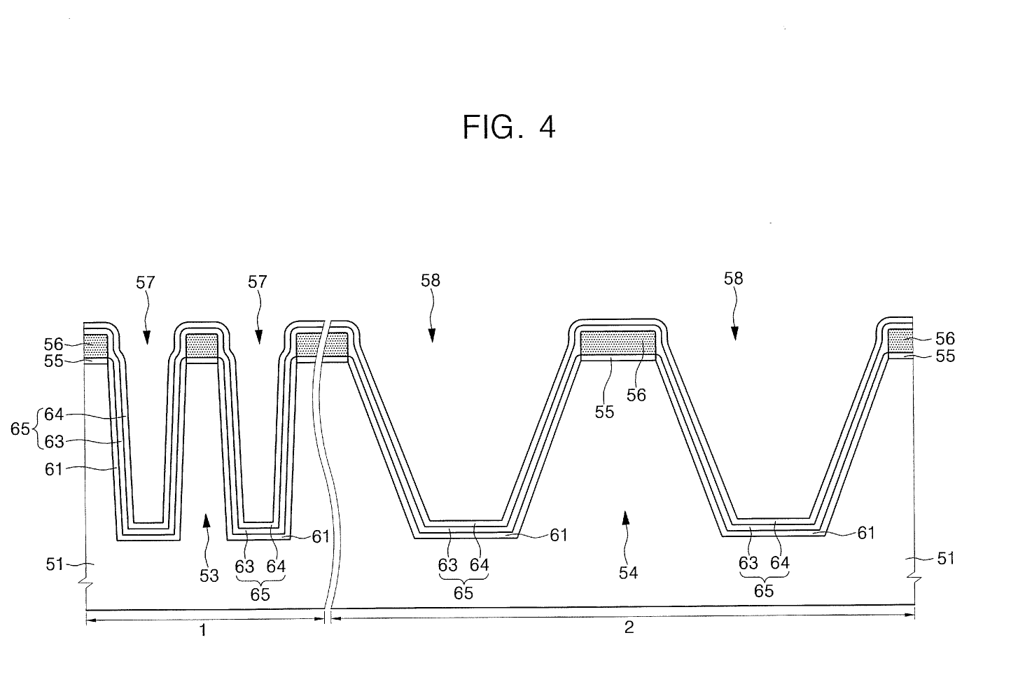

Referring next to FIG. 4, the semiconductor substrate 51, including the first and second trenches 57 and 58, may be thermally oxidized to form a sidewall oxide layer 61 on inner walls of the first and second trenches 57 and 58. The sidewall oxide layer 61 may be a silicon oxide layer formed by a thermally oxidation method. The sidewall oxide layer 61 may serve to cure etch damages applied to the semiconductor substrate 51 during the anisotropic etching process.

A conformal liner 65 may be formed on the entire surface of the semiconductor substrate 51 including the sidewall oxide layer 61. The liner 65 may include a sequentially stacked first liner 63 and second liner 64. Each of the first liner 63 and the second liner 64 may be formed, for example, of a silicon nitride layer, a silicon oxynitride layer, a silicon oxide layer, or a combination layer thereof. In some embodiments one or more of the sidewall oxide layer 61, the first liner 63, and the second liner 64 may be omitted.

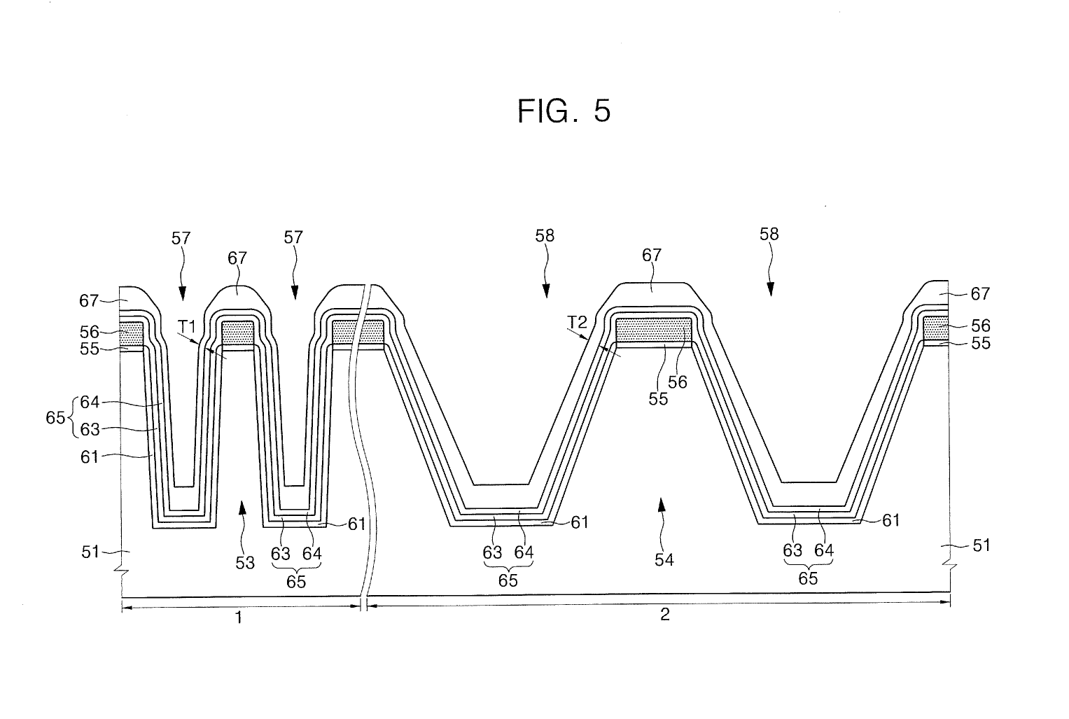

Referring now to FIGS. 5 and 13, a first HDPCVD technique is applied to the semiconductor substrate 51 including the liner 65 to form a lower isolation layer 67. That is, the lower isolation layer 67 may be formed of a first HDP oxide layer.

A HDPCVD apparatus, as shown in FIG. 13, may include a HDPCVD reactor 90, a substrate support 93, a cooling pipe 94, a gas pipe 96, a bias power source 95, an induction coil 97, and a plasma power source 98.

The substrate support 93 is shown mounted inside the HDPCVD reactor 90. The substrate support 93 may act to fix the semiconductor substrate 51. An electro static chuck (ESC) or the like may be used as the substrate support 93. The cooling pipe 94 is shown mounted inside the substrate support 93 to provide a path for circulating a coolant. The bias power source 95 may be electrically connected to the substrate support 93 to supply the bias power thereto. The gas pipe 96 may be mounted on the HDPCVD reactor 90 to supply a silicon source gas, an inert gas, and/or a reactive gas. The induction coil 97 may be laid outside the HDPCVD reactor 90. The plasma power source 98 may be electrically connected to the induction coil 97 to supply the plasma power.

In some embodiments, the process of forming the lower isolation layer 67 using the first HDPCVD technique may include positioning the semiconductor substrate 51 including the first and second trenches 57 and 58 on the substrate support 93. A plasma power of 5000 W to 10000 W may be applied to the induction coil 97. In addition, a bias power of 3000 W to 4000 W may be applied to the substrate support 93. The silicon source gas, the inert gas, and a first reactive gas may be supplied to the HDPCVD reactor 90 through the gas pipe 96. The silicon source gas may be, for example, SiH₄. The inert gas may be, for example, He gas and/or Ar gas. The first reactive gas may be, for example, H₂ and/or O₂.

In some embodiments, the semiconductor substrate 51 is adjusted to a temperature of about 200□ to about 500□. However, the semiconductor substrate 51 may be heated to a high temperature by the plasma power and/or the bias power. The temperature of the semiconductor substrate 51 may be adjusted by supplying a coolant into the cooling pipe 94 mounted inside the substrate support 93. The coolant may use inert gases, such as He gas, Ar gas, and/or neon (Ne) gas. In particular, the He gas is used in some embodiments. When the substrate support 93 is an ESC, the semiconductor substrate 51 may be held closely adhered to the substrate support 93, which may facilitate control of the temperature of the semiconductor substrate 51 by cooling of the substrate support 93. For example, in some embodiments, a bias power of 3300 W may be applied to the substrate support 93, and the temperature of the semiconductor substrate 51 may be adjusted to 350□.

For the described process, the lower isolation layer 67 may conformally cover the entire surface of the semiconductor substrate 51 including the liner 65. The lower isolation layer 67 shown in FIG. 5 has a first thickness T1 on an upper sidewall of the first trench 57 and a second thickness T2 on an tipper sidewall of the second trench 58.

As described above, the first HDPCVD technique may be a low temperature process controlled by adjusting the temperature of the semiconductor substrate 51 in a range of about 200□ to about 500□. The low temperature process may have a relatively high sticking coefficient compared to the conventional higher temperature HDPCVD technique. That is, the low temperature process may relatively increase the thickness of the HDP oxide layer deposited on the sidewall compared to the conventional HDPCVD technique.

However, as described above with reference to FIG. 3, the sidewalls of the second active region 54 have gentler slopes than the sidewalls of the first active region 53. Accordingly, the second thickness T2 may be significantly larger than the first thickness T1. The second thickness T2 may be more than one and a half times as large as the first thickness T1 in some embodiments. In some embodiments, the second thickness T2 may be one and a half times to four times as large as the first thickness T1. The second thickness T2 may be about 10 nm to about 100 nm.

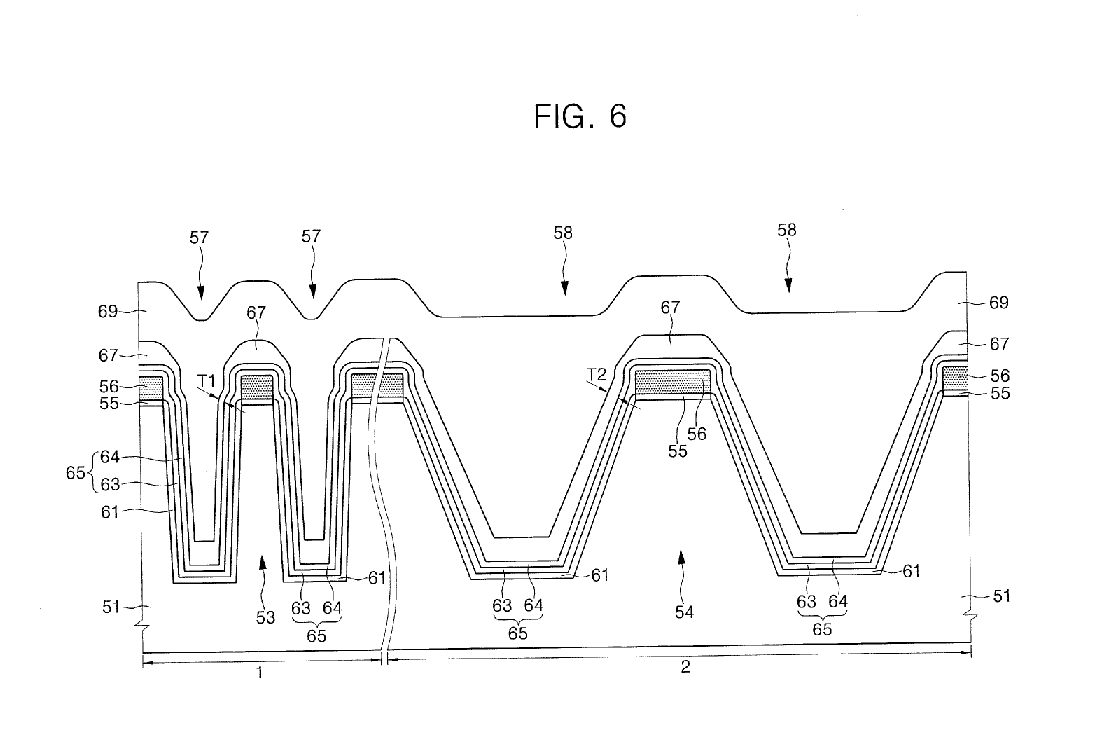

Referring next to FIGS. 6 and 13, an tipper isolation layer 69 is formed on the semiconductor substrate 51 including the lower isolation layer 67. The upper isolation layer 69 may completely fill the first and second trenches 57 and 58 using a second HDPCVD technique. That is, the upper isolation layer 69 may be formed as a second HDP oxide layer.

The process of forming the upper isolation layer 69 using the second HDPCVD technique may include preparing the semiconductor substrate 51 including the lower isolation layer 67 on the substrate support 93. A plasma power of 5000 W to 10000 W may be applied to the induction coil 97 in some embodiments. In addition, a bias power of 3000 W to 6000 W may be applied to the substrate support 93. A silicon source gas, an inert gas, and a second reactive gas may be supplied to the HDPCVD reactor 90 through the gas pipe 96. The silicon source gas may be, for example, SiH₄. The inert gas may be, for example, He gas or Ar gas. The second reactive gas may be, for example, H₂, O₂, and/or NF₃. In some embodiments, the temperature of the semiconductor substrate 51 is adjusted to a range of about 400□ to about 800□.

The process of forming the upper isolation layer 69 using the second HDPCVD technique may include a deposition process and a sputter etching process, which may be alternately and repeatedly performed. High bias power may be used to minimize the overhang and have better buried properties of the trenches 57 and 58. For example, a bias power of 5500 W may be applied to the substrate support 93 in some embodiments. The sidewalls of the second active region 54 may be still be protected by the lower isolation layer 67 having the second thickness T2. That is, the lower isolation layer 67 having the second thickness T2 may act to suppress plasma damage from occurring oil the sidewalls of the second active region 54.

As described above, the lower isolation layer 67 may be formed of the first HDP oxide layer, and the upper isolation layer 69 may be formed of the second HDP oxide layer. In some embodiments, the lower isolation layer 67 is formed at a lower temperature than the upper isolation layer 69. That is, the first HDP oxide layer may be formed at a lower temperature than the second HDP oxide layer. In addition, the first HDP oxide layer and the second HDP oxide layer may be concurrently formed within the same equipment.

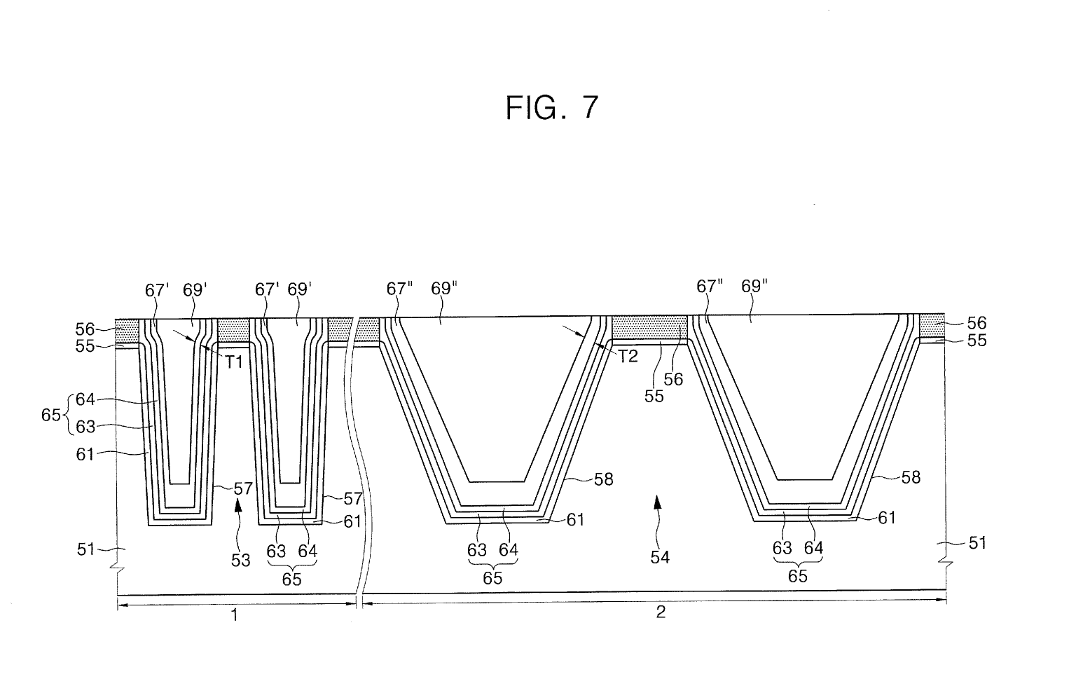

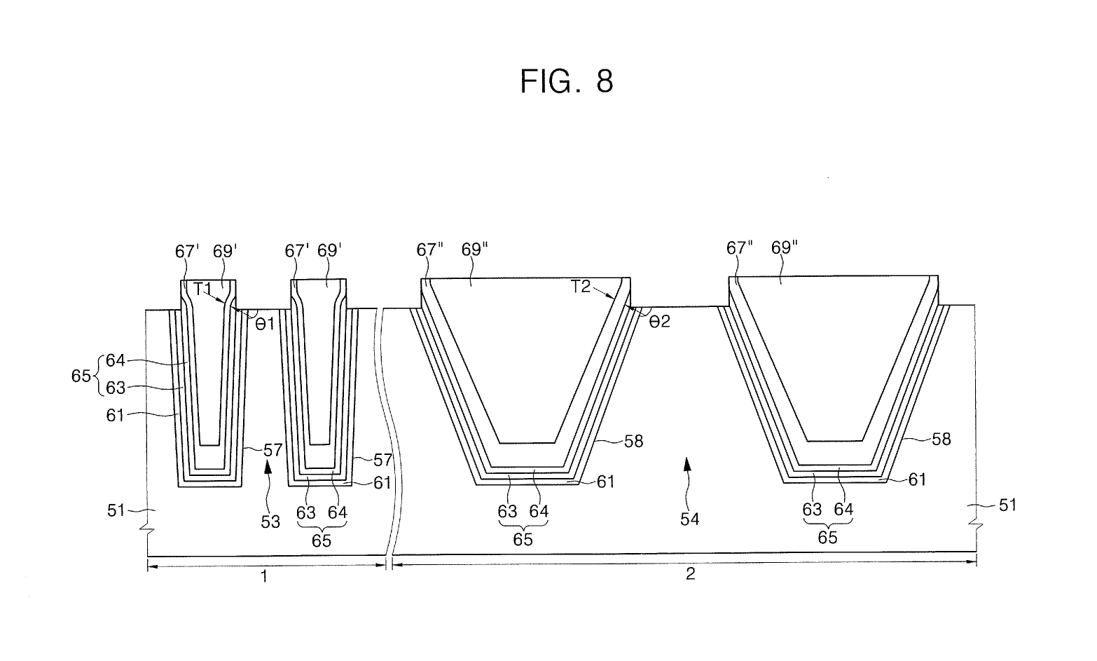

As shown in FIG. 7, the upper isolation layer 69 and the lower isolation layer 67 may be planarized to expose the pad nitride pattern 56. A chemical mechanical polishing (CMP) process and/or an etch back process may be used for planarization. As a result, a first lower isolation pattern 67′ may be formed within the first trench 57, and a first upper isolation pattern 69′ may be formed on the first lower isolation pattern 67′. In addition, a second lower isolation pattern 67″ may be formed within the second trench 58, and a second upper isolation pattern 69″ may be formed on the second lower isolation pattern 67″. As shown in FIG. 8, the pad nitride pattern 56 and the pad oxide pattern 55 may be selectively removed to expose top surfaces of the active regions 53 and 54.

Trench isolation methods according to further embodiments of the present invention will now be described with reference to FIGS. 9 to 13. Referring first to FIG. 9, a method substantially as described with reference to FIGS. 3-6 may be used to form first trenches 57 defining a first active region 53 in a first region 1 of a semiconductor substrate 51 and second trenches 58 defining a second active region 54 in a second region 2 of the semiconductor substrate 51. Subsequently, the lower isolation layer 67 and the upper isolation layer 69 may be sequentially formed substantially as described previously. Accordingly, operations For forming these layers will not be further described herein.

As seen in FIG. 9, the upper isolation layer 69 may be formed conformally cover the first and second trenches 57 and 58, for example, using the second HDPCVD technique described above.

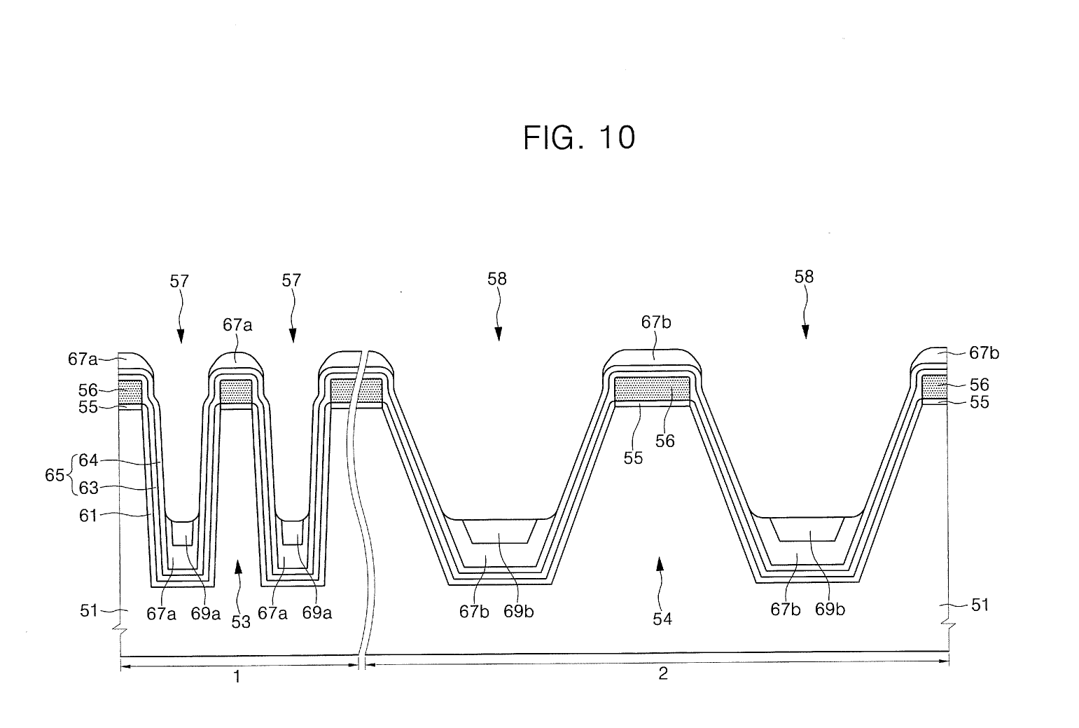

Referring now to FIG. 10, the tipper isolation layer 69 and the lower isolation layer 67 may be etched to form a first buried lower isolation pattern 67a and a first buried upper isolation pattern 69a, which are sequentially stacked on a bottom surface of the first trench 57 and to concurrently form a second buried lower isolation pattern 67b and a second buried upper isolation pattern 69b, which are sequentially stacked on a bottom surface of the second trench 58. The process used for etching the upper isolation layer 69 and the lower isolation layer 67 may be, for example, a wet etching process. The wet etching process may use, for example, an oxide etchant containing HF acid. As shown in FIG. 10, the liner 65 may be exposed on upper sidewalls of the first and second trenches 57 and 58.

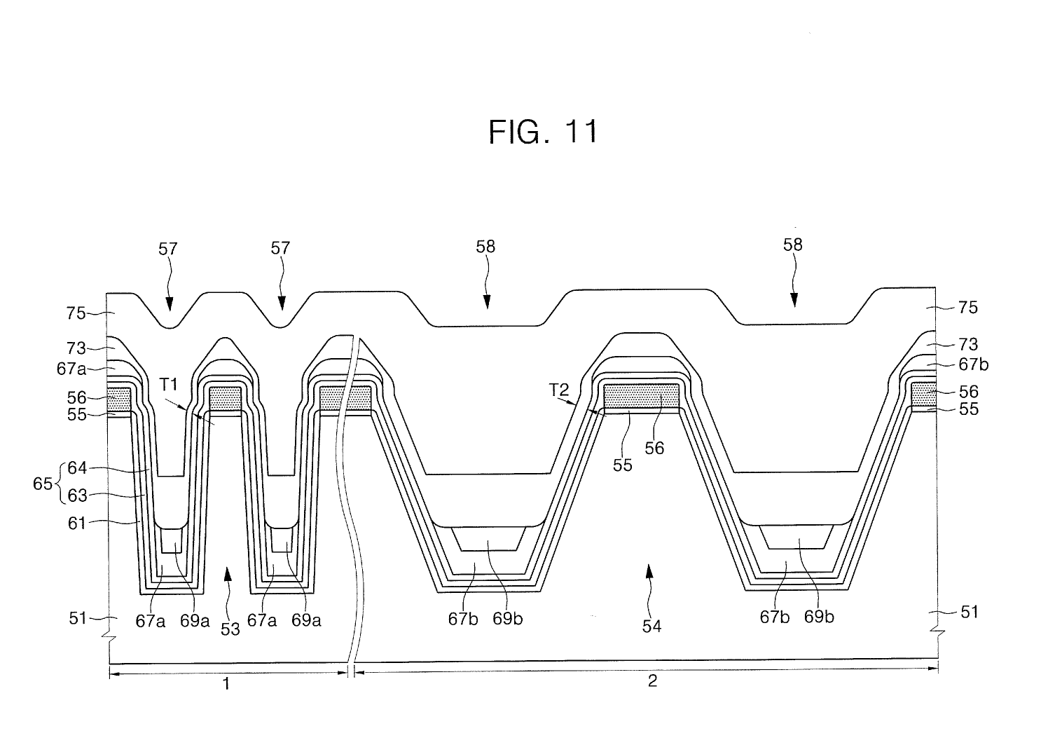

Referring next to FIGS. 11 and 13, a further lower isolation layer 73 and a further upper isolation layer 75 may be sequentially formed on the semiconductor substrate 51 including the first and second buried upper isolation patterns 69a and 69b.

In some embodiments, the lower isolation layer 73 is formed using the first HDPCVD technique described above. The process of forming the lower isolation layer 73 using the first HDPCVD technique may include mounting the semiconductor substrate 51 including the first and second buried upper isolation patterns 69a and 69b on the substrate support 93. A plasma power of about 5000 W to about 10000 W may be applied to the induction coil 97. In addition, a bias power of about 3000 W to about 4000 W may be applied to the substrate support 93. A silicon source gas, an inert gas, and a first reactive gas may be supplied to the HDPCVD reactor 90 through the gas pipe 96. The silicon source gas may be, for example, SiH₄. The inert gas may be, for example, He gas and/or Ar gas. The First reactive gas may be, for example, H₂ and/or O₂.

In some embodiments, the temperature of the semiconductor substrate 51 is adjusted in a range of about 200° C. to about 500° C. However, the semiconductor substrate 51 may be heated to a higher temperature by the plasma power and/or the bias power. The temperature of the semiconductor substrate 51 may be adjusted by supplying a coolant into the cooling pipe 94 mounted inside the substrate support 93. The coolant may use inert gases, such as He gas, Ar gas, and/or neon (Ne) gas. In some embodiments, the He gas may have excellent cooling performance.

When the substrate support 93 is an ESC, the semiconductor substrate 51 is may be mounted and held closely adhered to the substrate support 93. As such, the temperature of the semiconductor substrate 51 may be more efficiently controlled by cooling the substrate support 93.

As a result, the lower isolation layer 73 may be formed of a first HDP oxide layer. In addition, the lower isolation layer 73 may conformally cover the entire surface of the semiconductor substrate 51 including the first and second buried upper isolation patterns 69aand 69b. In some embodiments, the lower isolation layer 73 has a first thickness T1 on an upper sidewall of the first trench 57 and a second thickness T2 on an upper sidewall of the second trench 58.

As described above, the first HDPCVD technique uses a low temperature process, controlling the temperature of the semiconductor substrate 51 to a selected temperature from about 200° C. to about 500° C. The low temperature process may have a relatively high sticking coefficient compared to a conventional, higher temperature, HDPCVD technique. That is, the low temperature process may relatively increase the thickness of a HDP oxide layer deposited on a sidewall compared to the conventional HDPCVD technique.

However, as described above with reference to the embodiments of FIG. 3, the sidewalls of the second active region 54 have gentler slopes than the sidewalls of the first active region 53. Accordingly, the second thickness T2 may be significantly larger than the first thickness T1. The second thickness T2 may be more than one and a half times as large as the first thickness T1. For example, in some embodiments, the second thickness T2 may be one and a half times to four times as large as the first thickness T1. The second thickness T2 may be about 10 nm to about 100 nm.

Another upper isolation layer 75 is formed on the semiconductor substrate 51 including the other lower isolation layer 73. The upper isolation layer 75 may completely fill the first and second trenches 57 and 58 and may be formed using the second HDPCVD technique described previously. Thus, the upper isolation layer 75 may be a second HDP oxide layer.

The process of forming the upper isolation layer 75 using the second HDPCVD technique may include positioning the semiconductor substrate 51 including the lower isolation layer 73 on the substrate support 93. A plasma power of about 5000 W to about 10000 W may be applied to the induction coil 97. In addition, a bias power of about 3000 W to about 6000 W may be applied to the substrate support 93. A silicon source gas, an inert gas, and a second reactive gas may be supplied to the HDPCVD reactor 90 through the gas pipe 96. The silicon source gas may be SiH₄. The inert gas may be He gas and/or Ar gas. The second reactive gas may be H₂, O₂, and/or NF₃. In some embodiments, the temperature of the semiconductor substrate 51 is adjusted in a range of about 400° C. to about 800° C.

The process of forming the other upper isolation layer 75 using the second HDPCVD technique may include a deposition process and a sputter etching process, which may be alternately and repeatedly performed. As described above, high bias power may be advantageously used to minimize the overhang and may provide better buried properties of the trenches 57 and 58. For example, a bias power of 5500 W may be applied to the substrate support 93. Nonetheless, in some embodiments, the sidewalls of the second active region 54 may be protected by the lower isolation layer 73 having the second thickness T2. That is, the lower isolation layer 73 having the second thickness T2 may act to suppress plasma damage from occurring on the sidewalls of the second active region 54.

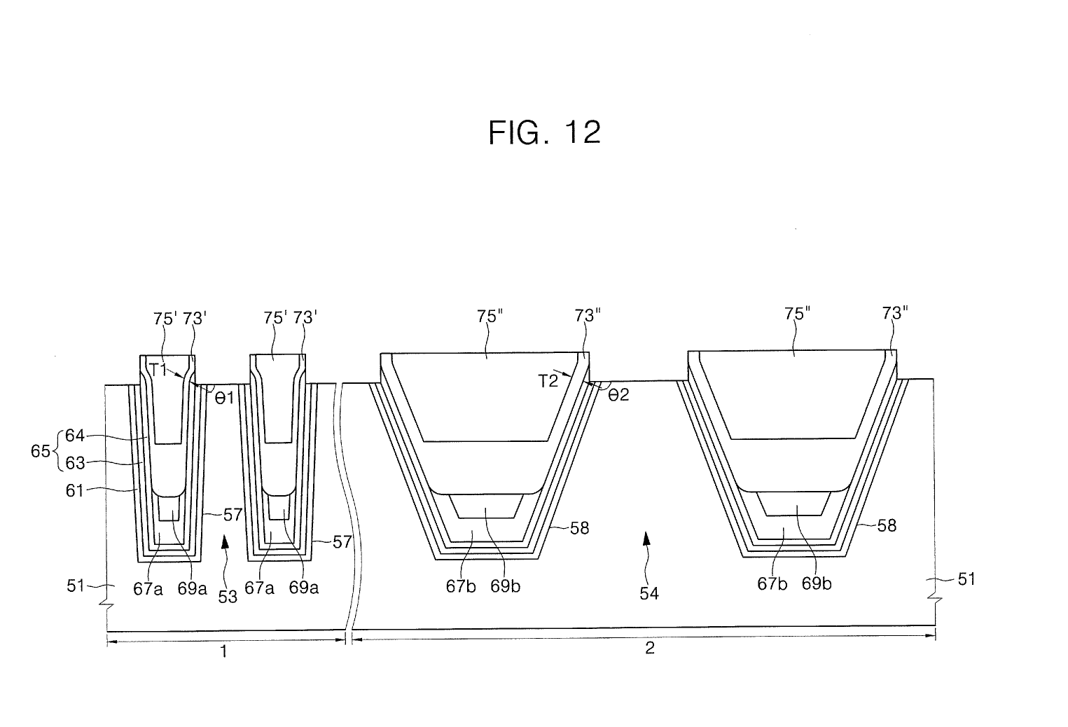

Referring to FIG. 12, the upper isolation layer 75 and the lower isolation layer 73 may be planarized to expose the pad nitride pattern 56. A CMP process and/or an etch back process may be applied for the planarization. As a result, a first lower isolation pattern 73′ may be formed within the first trench 57, and a first upper isolation pattern 75′ may be formed on the first lower isolation pattern 73′. In addition, a second lower isolation pattern 73″ may be formed within the second trench 58, and a second upper isolation pattern 75″ may be formed on the second lower isolation pattern 73″. Subsequently, the pad nitride pattern 56 and the pad oxide pattern 55 may be selectively removed to expose top surfaces of the active regions 53 and 54 as seen in FIG. 12. Layers 67a, 67b are also removed in the described operations to expose the pad nitride pattern 56.

Hereinafter, a trench isolation structure according to some embodiments of the present invention will be further described with reference FIG. 8. As seen in FIG. 8, first trenches 57 are formed in the first region 1 of the semiconductor substrate 51 to define the first active region 53. In addition, second trenches 58 are formed in the second region 2 of the semiconductor substrate 51 to define the second active region 54. The first region 1 may be a cell region, and the second region 2 may be a peripheral circuit region. The first active region 53 and the second active region 54 may be formed in the shape of a trapezoid having a top width smaller than the bottom width.

The second trenches 58 may have larger widths than the first trenches 57. That is, the second trenches 58 having larger widths than the first trenches 57 may be formed in the second region 2. Sidewalls of the first active region 53 may have different slopes from sidewalls of the second active region 54. A first crossing angle θ1 is formed between a top surface and the sidewall of the first active region 53, and a second crossing angle θ2 is formed between a top surface and the sidewall of the second active region 54. The second crossing angle θ2 may be larger than the first crossing angle θ1. That is, the sidewalls of the first active region 53 may have slopes close to 90°, whereas the sidewalls of the second active region 54 may have gentler (less steep) slopes than the sidewalls of the first active region 53.

The sidewall oxide layer 61 may be formed on inner walls of the first and second trenches 57 and 58. The sidewall oxide layer 61 may be a silicon oxide layer. The liner 65 may be formed on inner walls of the first and second trenches 57 and 58 on the sidewall oxide layer 61. The liner 65 may include the first liner 63 and the second liner 64, which may be sequentially stacked. Each of the first liner 63 and the second liner 64 may be formed of a silicon nitride layer, a silicon oxynitride layer, a silicon oxide layer, or a combination layer thereof. In some embodiments, the sidewall oxide layer 61, the first liner 63, and/or the second liner 64 may be omitted.

The first lower isolation pattern 67′ is formed within the first trench 57 on the liner 65. The first lower isolation pattern 67′ may be a first HDP oxide layer. The first lower isolation pattern 67′ has a first thickness Ti on an upper sidewall of the first trench 57. The first upper isolation pattern 69′ is formed on the first lower isolation pattern 67′. The first upper isolation pattern 69′ may be a second HDP oxide layer.

A second lower isolation pattern 67″ is formed within the second trench 58 on the liner 65. The second lower isolation pattern 67″ may be the same material as the first HDP oxide layer forming the first lower isolation layer pattern 67′. The second lower isolation pattern 67″ illustrated in FIG. 8 has a second thickness T2 larger than the first thickness T1 on an upper sidewall of the second trench 58. The second thickness T2 may be about 10 nm to about 100 nm. The second thickness T2 may be more than one and a half times as large as the first thickness. The second upper isolation pattern 69″ is formed on the second lower isolation pattern 67″. The second upper isolation pattern 69″ may be the same material as the second HDP oxide layer forming the first upper isolation pattern 69′.

The first lower isolation pattern 67′ and the second lower isolation pattern 67″ may act as a lower isolation layer. The first upper isolation pattern 69′ and the second upper isolation pattern 69″ may act as an upper isolation layer.

A trench isolation structure according to further embodiments of the present invention will now be further described with reference back to FIG. 12. Referring to FIG. 12, first trenches 57 are formed in the first region 1 of the semiconductor substrate 51 to define the first active region 53. In addition, second trenches 58 are formed in the second region 2 of the semiconductor substrate 51 to define the second active region 54. The second trenches 58 may have larger widths than the first trenches 57. Sidewalls of the first active region 53 may have different slopes from sidewalls of the second active region 54. That is, the sidewalls of the first active region 53 may have slopes close to 90°, whereas the sidewalls of the second active region 54 may have gentler (less steep) slopes than the sidewalls of the first active region 53.

A sidewall oxide layer 61 may be formed on inner walls of the first and second trenches 57 and 58. The sidewall oxide layer 61 may be a silicon oxide layer. A liner 65 may be formed on inner walls of the first and second trenches 57 and 58 on the sidewall oxide layer 61. The liner 65 may include a first liner 63 and a second liner 64, which may be sequentially stacked. Each of the first liner 63 and the second liner 64 may be formed of a silicon nitride layer, a silicon oxynitride layer, a silicon oxide layer, or a combination layer thereof. In some embodiments, the sidewall oxide layer 61, the first liner 63, and/or the second liner 64 may be omitted.

The first buried lower isolation pattern 67a is shown formed on a bottom surface of the first trench 57. The first buried lower isolation pattern 67a may be a first HDP oxide layer. The first buried upper isolation pattern 69a is formed on the first buried lower isolation pattern 67a. The first buried upper isolation pattern 69a may be a second HDP oxide layer. The first lower isolation pattern 73′ is formed on the first buried upper isolation pattern 69a. The first lower isolation pattern 73′ is disposed within the first trench 57, and has a first thickness T1 on an upper sidewall of the first trench 57. The first lower isolation pattern 73′ may be formed of the same material as the first HDP oxide layer pattern 67a. The first upper isolation pattern 75′ is formed on the first lower isolation pattern 73′. The first upper isolation pattern 75′ may be the same material as the second HDP oxide layer pattern 69a.

The second buried lower isolation pattern 67b is formed on a bottom surface of the second trench 58. The second buried lower isolation pattern 67b may be the same material as the first HDP oxide layer pattern 67a. The second buried upper isolation pattern 69b is disposed on the second buried lower isolation pattern 67b. The second buried upper isolation pattern 69b may be the same material as the second HDP oxide layer pattern 69a. The second lower isolation pattern 73″ is disposed on the second buried upper isolation pattern 69b. The second lower isolation pattern 73″ is disposed within the second trench 58, and has a second thickness T2 larger than the first thickness T1 on an upper sidewall of the second trench 58. The second thickness T2 may be about 10 nm to about 100 nm. The second thickness T2 may be more than one and a half times as large as the first thickness. The second lower isolation pattern 73″ may also be the same material as the first HDP oxide layer pattern 67a. The second upper isolation pattern 75″ is formed on the second lower isolation pattern 73″. The second upper isolation pattern 75″ may also be the same material as the second HDP oxide layer pattern 69a.

The first lower isolation pattern 73′ and the second lower isolation pattern 73″ may act as a lower isolation layer. The first upper isolation pattern 75′ and the second upper isolation pattern 75″ may act as an upper isolation layer.

According to some embodiments of the present invention as described above, a first trench and a second trench having a larger width than the first trench are formed in predetermined regions of a semiconductor substrate. A first HDPCVD technique is employed to form a lower isolation layer having a first thickness on an upper sidewall of the first trench and a second thickness on an upper sidewall of the second trench. The second thickness may be larger than the first thickness. Subsequently, an upper isolation layer is formed on the semiconductor substrate having the lower isolation layer. While the upper isolation layer is formed, the lower isolation layer having the second thickness acts to suppress plasma damage from occurring on sidewalls of the second trench. Accordingly, the process of forming the upper isolation layer may employ a second HDPCVD technique using high bias power. Consequently, a trench having a high aspect ratio and a trench having a large width can be simultaneously filled with a HDP oxide layer having a buried lower isolation layer thereunder.

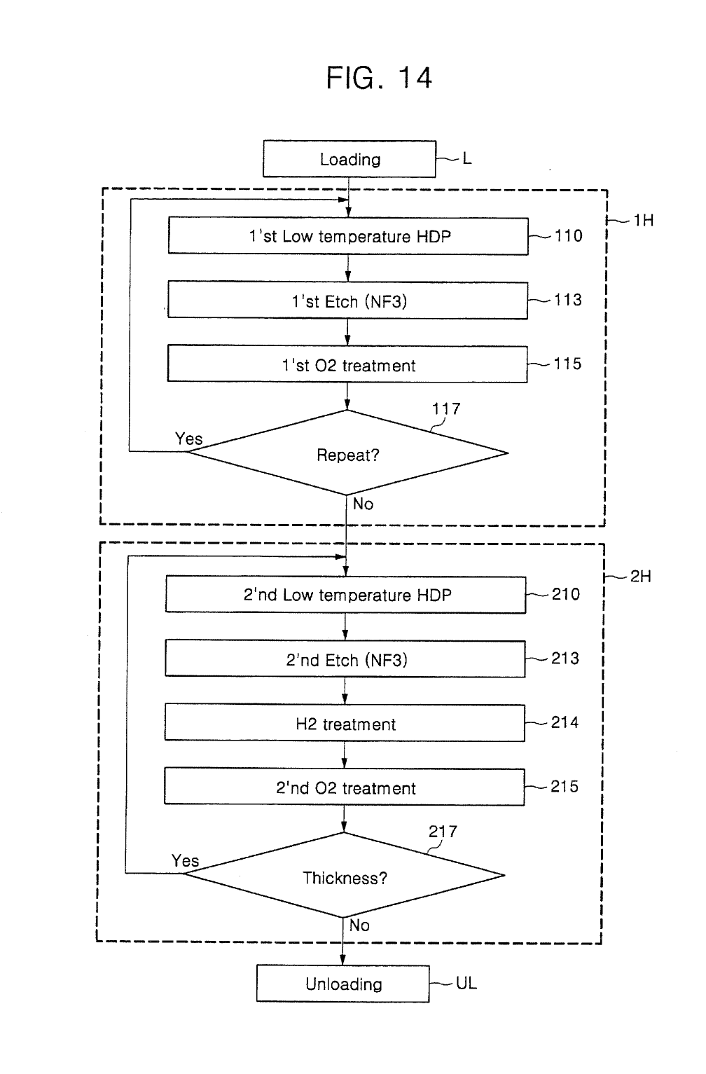

Further embodiments of the present invention will now be described. FIG. 14 is a flowchart illustrating a trench isolation method according to some embodiments of the present invention.

Referring to the trench isolation method of the embodiments illustrated in FIG. 14, the method includes: loading a semiconductor substrate into a high density plasma chemical vapor deposition (HDPCVD) reactor (block L); performing a first low temperature HDP deposition (block 110); performing a first etch (block 113); performing a first oxygen (O₂) treatment (block 115); repeatedly performing the first low temperature HDP deposition through the first O₂ treatment of blocks 110-115 (block 117); performing a second low temperature HDP deposition (block 210); performing a second etch (block 213); performing a hydrogen (H₂) treatment (block 214); performing a second O₂ treatment (block 215) and repeatedly performing the second low temperature HDP deposition through the second O₂ treatment of blocks 210-215 (block 217). The semiconductor substrate is then unloaded from the reactor (block UL). In some embodiments, the first etch (block 113) and the first O₂ treatment (block 115) may be performed concurrently without removing the substrate from the chamber.

The first low temperature HDP deposition (block 110) through the repeated performing of the first low temperature HDP deposition to the first O₂ treatment of blocks 110-115 (block 117) may be referred to herein as a first high density plasma deposition process 1H. The second low temperature HDP deposition (block 210) through the repeated performing of the second low temperature HDP deposition (210) to the second O₂ treatment of blocks 210-215 (block 217) may be referred to herein as a second high density plasma deposition process 2H. In other words, the trench isolation method illustrated in FIG. 14 may include the first high density plasma deposition process 1H and the second high density plasma deposition process 2H.

Substantially as was described above with reference to the embodiments of FIG. 13, the apparatus used for performing the illustrated trench isolation method of FIG. 14 may be a HDPCVD apparatus. As shown in FIG. 13, the HDPCVD apparatus may include a HDPCVD reactor 90, a substrate support 93, a cooling pipe 94, a gas pipe 96, a bias power source 95, an induction coil 97, and a plasma power source 98. The method of FIG. 14 will now be more fully described with reference to FIGS. 13 and 14.

Referring to FIGS. 13 and 14, loading the semiconductor substrate into the HDPCVD reactor 90 (block L) may include positioning the semiconductor substrate on the substrate support 93. The semiconductor substrate may have a cell active region defined by a first trench and a peripheral active region defined by a second trench. The cell active region and the first trench may be formed in a cell region of the semiconductor substrate, and the peripheral active region and the second trench may be formed in a peripheral circuit region of the semiconductor substrate. The second trench may have a larger width than the first trench. Inner walls of the first and second trenches may be covered with a sidewall oxide layer and a nitride liner. That is, the sidewall oxide layer and the nitride liner may be sequentially stacked on sidewalls of the cell and peripheral active regions. The sidewall oxide layer may be formed of silicon oxide, such as thermal oxide. The nitride liner may be formed of silicon nitride, silicon oxynitride and/or silicon oxide.

The first low temperature HDP deposition (block 110) may include applying a bias power of 2500 W to 4500 W to the substrate support 93 and applying a plasma power of 1000 W to 7000 W to the induction coil 97. A coolant may be supplied to the cooling pipe 94 and a silicon source gas may be provided to the HDPCVD reactor 90 through the gas pipe 96.

The application of a plasma power of 1000 W to 7000 W to the induction coil 97 may include applying different power levels to different induction coils 97. For example, a plasma power of 5000 W to 7000 W may be applied to the induction coil 97 disposed over the HDPCVD reactor 90 and a plasma power of 1000 W to 3000 W may be applied to the induction coil 97 disposed at the side of the HDPCVD reactor 90 in some embodiments.

The coolant may be an inert gas or gases, such as helium (He), argon (Ar) and/or neon (Ne) gases. In some embodiments, a He gas as a coolant exhibits favorable cooling performance.

The semiconductor substrate may be adjusted to a temperature of about 200° C. to about 500° C. The temperature of the semiconductor substrate may be controlled by the coolant supplied to the cooling pipe 94.

In some embodiments, the substrate support 93 is an electrostatic chuck (ESC) and the semiconductor substrate may be held closely adhered to the substrate support 93. This may facilitate control of the temperature of the semiconductor substrate by adjusting the amount of cooling of the substrate support 93. In some embodiments, the semiconductor substrate is maintained at a temperature of about 350° C.

The silicon source gas may be SiH₄. While the silicon source gas is supplied, inert and reactive gases may also be concurrently supplied. For example, the inert gas may be He and the reactive gas may be O₂.

The first etch (block 113) may include applying a bias power of about 1300 W to about 2300 W to the substrate support 93, applying a plasma power of about 1000 W to about 7000 W to the induction coil 97 and supplying an etch gas to the HDPCVD reactor 90 through the gas pipe 96. The etch gas may be a mixture gas containing NF₃. During this process, the semiconductor substrate may be maintained at a temperature of about 200° C. to about 500° C. For example, the temperature of the semiconductor substrate may be adjusted to about 500° C.

The first O₂ treatment (block 115) may include applying a plasma power of about 1000 W to about 7000 W to the induction coil 97 and supplying O₂ to the HDPCVD reactor 90 through the gas pipe 96. During this process, the semiconductor substrate may be maintained at a temperature of about 200° C. to 500° C. In particular embodiments, the temperature of the semiconductor substrate may be adjusted to about 500° C. Under these conditions, the first etch (block 113) and the first O₂ treatment (block 115) may be performed concurrently without removing the substrate from the chamber.

The repeated performing (block 117) of the first low temperature HDP deposition (block 110) through the first O₂ treatment (block 115) may include repeatedly performing the first low temperature HDP deposition (block 110) through the first O₂ treatment (block 115) a selected number of times. For example, the first low temperature HDP deposition (block 110) to the first O₂ treatment (block 115) may be performed twice.

As described above, the first low temperature HDP deposition (block 110) through the repeated performing (block 117) of the first low temperature HDP deposition (block 110) through the first O₂ treatment (block 115) may be referred to as the first high density plasma deposition process 1H. As a result of the first high density plasma deposition process 1H, a lower isolation layer may be formed having a first thickness on a sidewall of the first trench and a second thickness on a sidewall of the second trench. In some embodiments, the second thickness may be larger than the first thickness. For example, the second thickness may be at least 1.5 times larger than the first thickness.

The second low temperature HDP deposition (block 210) may include applying a bias power of 2500 W to 4500 W to the substrate support 93, applying a plasma power of 1000 W to 7000 W to the induction coil 97, supplying a coolant to the cooling pipe 94, and supplying a silicon source gas to the HDPCVD reactor 90 through the gas pipe 96.

The second low power HDP deposition (block 210) may be performed under substantially the same conditions as the first low temperature HDP deposition (block 110). In particular, the application of a plasma power of 1000 W to 7000 W to the induction coil 97 may be separately controlled for respective induction coils 97 at different positions relative to the substrate. In some embodiments, a plasma power of 5000 W to 7000 W is applied to the induction coil 97 deposited over the HDPCVD reactor 90 while applying a plasma power of 1000 W to 3000 W to the induction coil(s) 97 disposed at the side(s) of the HDPCVD reactor 90.

The coolant may use inert gases such as He, Ar and/or Ne. The temperature of the semiconductor substrate may be adjusted to about 200° C. to 500° C. The temperature of the semiconductor substrate may be controlled/adjusted using the coolant provided to the cooling pipe 94. For example, the temperature of the semiconductor substrate may be maintained at about 350° C. in some embodiments. The silicon source gas may be SiH₄. While the silicon source gas is supplied, inert and/or reactive gases may be also be supplied to the chamber. For example, the inert gas may be He and the reactive gas may be O₂.

The second etch (block 213) may include applying a bias power of 1300 W to 2300 W to the substrate support 93, applying a plasma power of 1000 W to 7000 W to the induction coil 97, and supplying an etch gas to the HDPCVD reactor 90 through the gas pipe 96. The etch gas may be a mixture gas containing NF₃. At this time, the temperature of the semiconductor substrate may be adjusted to about 200° C. to 500° C. For example, the temperature of the semiconductor substrate may be adjusted to about 500° C. The second etch (block 213) may be performed under substantially the same conditions as the first etch (block 113).

The H₂ treatment (block 214) may include applying a bias power of 2000 W to 4000 W to the substrate support 93, applying a plasma power of 1000 W to 7000 W to the induction coil 97, and supplying H₂ gas to the HDPCVD reactor 90 through the gas pipe 96. At this time, the temperature of the semiconductor substrate may be adjusted to about 200° C. to 500° C. For example, the temperature of the semiconductor substrate may be adjusted to about 500° C. While the H₂ gas is supplied, an inert gas, such as He, may also be supplied.

The second O₂ treatment (block 215) may include applying a plasma power of 1000 W to 7000 W to the induction coil 97, and supplying O₂ to the HDPCVD reactor 90 through the gas pipe 96. At this time, the temperature of the semiconductor substrate may be adjusted to about 200° C. to 5000° C. For example, the temperature of the semiconductor substrate may be adjusted to about 500° C. The second O₂ treatment (block 215) may be performed under substantially the same conductions as the first O₂ treatment (block 115).

The repeated performing (block 217) of the second low temperature HDP deposition through the second O₂ treatment of blocks 210-215 may include repeatedly performing the second low temperature HDP deposition through the second O₂ treatment a desired number of times to obtain a thin film formed to a desired thickness.

As described above, the second low temperature HDP deposition (block 210) through the repeated performing (block 217) of the second low temperature HDP deposition through the second O₂ treatment may constitute the second high density plasma deposition process 2H. Thereby, an upper isolation layer completely filling the first and second trenches may be formed in some embodiments.

The unloading operation (block UL) may include unloading the semiconductor substrate having the lower and upper isolation layers from the HDPCVD reactor 90.

As described above, the first etch (block 113) and the first O₂ treatment (block 115) may be concurrently performed without removing the substrate from the chamber. The first high density plasma deposition process 1H does not include the H₂ treatment (block 214). Accordingly, during the formation of the lower isolation layer, the sidewall oxide layer and the nitride liner may be preserved. Moreover, the upper isolation layer may exhibit an excellent gap fill characteristic as a result of the H₂ treatment (block 214). During the H₂ treatment (block 214), the lower isolation layer may protect the sidewall oxide layer and the nitride liner, which may significantly reduce sidewall oxide lifting.

In some embodiments, the lower isolation layer is formed by performing the first low temperature HDP deposition (block 110) through the first O₂ treatment (block 115) once or twice, and the upper isolation layer is formed using the second high density plasma deposition process 2H. Thus, an insulating layer significantly reducing sidewall oxide lifting, and having an excellent gap fill characteristic, may be formed by some embodiments of the present invention as illustrated in FIG. 14.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A trench isolation method, comprising:
forming a first trench and a second trench in a semiconductor substrate, the second trench having a larger width than the first trench;
forming a lower isolation layer on the semiconductor substrate, the lower isolation layer having a first thickness on an upper sidewall of the first trench and a second thickness on an upper sidewall of the second trench, using a first high density plasma deposition process, the second thickness being greater than the first thickness; and
forming an upper isolation layer on the semiconductor substrate including the lower isolation layer using a second high density plasma deposition process, different from the first high density plasma deposition process, the second high density plasma deposition process including an H₂ treatment process.

2. The trench isolation method of claim 1, wherein the first high density plasma deposition process comprises:
positioning the semiconductor substrate including the first and second trenches on a substrate support within a high density plasma chemical vapor deposition (HDPCVD) reactor; and then
performing a first low temperature HDP deposition process on the semiconductor substrate, including injecting a silicon source gas into the HDPCVD reactor;
performing a first etch on the semiconductor substrate, including injecting an etch gas into the high density plasma chemical vapor deposition reactor; and
performing a first O₂ treatment on the semiconductor substrate, including injecting O₂ into the HDPCVD reactor.

3. The trench isolation method of claim 2, wherein the first etch and the O₂ treatment are both performed without removing the semiconductor substrate from the HDPCVD reactor therebetween.

4. The trench isolation method of claim 2, wherein forming the lower isolation layer includes repeatedly performing the first low temperature HDP deposition process, the first etch and the first O₂ treatment before forming the upper isolation layer.

5. The trench isolation method of claim 2, wherein the silicon source gas comprises SiH₄, and the etch gas comprises NF₃.

6. The trench isolation method of claim 2, wherein the second high density plasma deposition process comprises the following carried out after forming the lower isolation layer:
performing second low temperature HDP deposition process on the semiconductor substrate, including injecting a silicon source gas into the HDPCVD reactor;
performing second etch on the semiconductor substrate, including injecting an etch gas into the HDPCVD reactor;
performing the H₂ treatment on the semiconductor substrate, including injecting H₂ into the HDPCVD reactor; and
performing a second O₂ treatment on the semiconductor substrate, including injecting O₂ into the HDPCVD reactor.

7. The trench isolation method of claim 6, wherein the second etch and the H₂ treatment are performed without removing the semiconductor substrate from the HDPCVD reactor therebetween.

8. The trench isolation method of claim 6, wherein the silicon source gas for the second low temperature HDP deposition process comprises SiH₄, and the etch gas for the second etch comprises NF₃.

9. The trench isolation method of claim 1, wherein the first and second high density plasma deposition processes include maintaining a temperature of the semiconductor substrate at about 200° C. to 500° C.

10. The trench isolation method of claim 9, wherein maintaining the temperature of the semiconductor substrate at about 200° C. to 500° C. includes supplying helium (He) gas to a cooling pipe coupled to a substrate support on which the semiconductor substrate is mounted to maintain the temperature of the semiconductor substrate.

11. The trench isolation method of claim 1, wherein forming the first trench and the second trench comprises:
forming a pad oxide pattern on the semiconductor substrate;
forming a pad nitride pattern on the pad oxide pattern; and
selectively etching the semiconductor substrate using the pad nitride pattern as an etch mask.

12. The trench isolation method of claim 1, wherein forming the first trench and the second trench is followed by forming a silicon oxide sidewall layer on inner walls of the first and second trenches by thermal oxidation.

13. The trench isolation method of claim 1, wherein forming the first trench and the second trench is followed by forming a liner conformally covering the semiconductor substrate including the first and second trenches, wherein the liner is a silicon nitride layer, a silicon oxynitride layer and/or a silicon oxide layer.

14. The trench isolation method of claim 1, wherein the second thickness is at least about one and a half times as large as the first thickness.

15. A trench isolation method, comprising:
forming a first trench and a second trench in a semiconductor substrate, the second trench having a larger width than the first trench; and
forming an isolation layer on the semiconductor substrate using a high density plasma deposition process, wherein the high density plasma deposition process comprises:
positioning the semiconductor substrate including the first and second trenches on a substrate support within a high density plasma chemical vapor deposition (HDPCVD) reactor;
performing a low temperature HDP deposition process on the semiconductor substrate, including injecting a silicon source gas into the HDPCVD reactor;
performing an etch on the semiconductor substrate, including injecting an etch gas into the HDPCVD reactor;
performing an H₂ treatment process on the semiconductor substrate, including injecting H₂ into the HDPCVD reactor; and performing an O₂ treatment on the semiconductor substrate, including injecting O₂ into the HDPCVD reactor.

16. The trench isolation method of claim 15, wherein performing the etch and performing the H₂ treatment process are performed without removing the semiconductor substrate from the HDPCVD reactor therebetween.

17. The trench isolation method of claim 15, wherein the silicon source gas comprises SiH₄, and the etch gas comprises NF₃.

18. The trench isolation method of claim 15, wherein forming the isolation layer includes maintaining a temperature of the semiconductor substrate at about 200° C. to 500° C. while the high density plasma deposition process is performed.

19. The trench isolation method of claim 18, wherein maintaining the temperature of the semiconductor substrate includes supplying helium (He) gas to a cooling pipe coupled to the substrate support.

20. The trench isolation method of claim 15, wherein forming the first trench and the second trench comprises:
forming a pad oxide pattern on the semiconductor substrate;
forming a pad nitride pattern on the pad oxide pattern; and
selectively etching the semiconductor substrate using the pad nitride pattern as an etch mask.

21. The trench isolation method of claim 15, wherein forming the first trench and the second trench is followed by forming a silicon oxide sidewall layer on inner walls of the first and second trenches by thermal oxidation.

22. The trench isolation method of claim 15, wherein forming the first trench and the second trench is followed by forming a liner conformally covering the semiconductor substrate including the first and second trenches, wherein the liner is a silicon nitride layer, a silicon oxynitride layer and/or a silicon oxide layer.
